(19) United States
(12) Patent Application Publication
(10) Pub. No.: US 2006/0270192 A1
(43) Pub. Date: Nov. 30, 2006

(54) SEMICONDUCTOR SUBSTRATE AND DEVICE WITH DEUTERATED BURIED LAYER

(75) Inventor: Kangguo Cheng, Beacon, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/908,722

(22) Filed: May 24, 2005

(51) Int. Cl. H01L 29/94; H01L 21/30

(52) U.S. Cl. 438/459; 257/368

(57) ABSTRACT

A method and structure for forming an SOI substrate and integrated circuit built on the SOI substrate contain deuterium in the buried insulator layer of the substrate. Deuterium in the buried insulator layer acts as a reservoir to supply deuterium in the entire device manufacturing process. It is in a quantity sufficient to diffuse out of the buried insulator layer to reach and passivate defects in the gate insulator and at the interface between the transistor body and the gate insulator and to replace deuterium that has diffused away from the interface.

### TECHNICAL FIELD

The field of the invention is that of semiconductor substrate and integrated circuit manufacturing, in particular semiconductor substrate and device having a deuterated buried layer.

### BACKGROUND OF THE INVENTION

Hydrogen passivation has become a well-known and established practice in the fabrication of semiconductor devices. In the hydrogen passivation process, defects which affect the operation of semiconductor devices are removed. For example, such defects have been described as recombination/generation centers on active components of semiconductor devices. These centers are thought to be caused by dangling bonds which introduce states in the energy gap which remove charged carriers or add unwanted charge carriers in the device, depending in part on the applied bias. While dangling bonds occur primarily at surfaces or interfaces in the device, they also are thought to occur at vacancies, micro pores, dislocations, and also to be associated with impurities.

Another problem which has arisen in the semiconductor industry is the degradation of device performance by hot carrier effects. This is particularly of concern with respect to smaller devices in which proportionally larger voltages are used. When such high voltages are used, channel carriers can be sufficiently energetic to enter an insulating layer and degrade device behavior. For example, in silicon-based P-channel MOSFETs, channel strength can be reduced by trapped holes in the oxide which lead to a positive oxide charge near the drain. On the other hand, in N-channel MOSFETs, gate-to-drain shorts may be caused by electrons entering the oxide and creating interface traps and oxide wear-out.

It is known in the art of integrated circuit fabrication that passivation of defects at the interface of the gate insulator and the semiconductor substrate of an in insulated gate field effect transistor (IGFET, including MOSFET) by deuterium offers advantages in improving device reliability compared with passivation by hydrogen or other methods.

It is also known that there are significant problems in implementing such passivation. Deuteration of the interface is conventionally done by annealing the wafer in deuterium before, during, and/or in the back end of line (BEOL) process.

If the deuteration of the interface is performed before the back end of line (BEOL) processing steps, the subsequent elevated temperatures will cause the deuterium to diffuse away from the interface and thus degrade the benefits of the deuterium. It has been proposed that the deuterium could be preserved by adding a diffusion barrier cap (e.g. a nitride cap) above the gate after the deuterium anneal, but this cap layer adds process complexity and cost.

When the deuterium anneal is done during or after the BEOL process, the anneal temperature must be less than 450° C. in order to avoid damage to the metallization. This low temperature means that the anneal time must be much greater than a corresponding anneal at a higher temperature in order to assure that the deuterium diffuses through the multiple interconnect layers in the back end to reach and passivate the gate oxide interface defects.

In addition, performing the deuterium anneal after BEOL process results in low deuteration efficiency because most interface defects may have already been passivated by hydrogen, since hydrogen is present in the BEOL processes such as film deposition, etching, ion implantation and cleaning, etc.

The art could benefit from a method of deuterium passivation that is economical to perform and a structure having a reservoir that supplies deuterium in the entire processing.

### SUMMARY OF THE INVENTION

The invention relates to a method of supplying deuterium for defect passivation in silicon-on-insulator (SOI), or similar, a semiconductor substrate and integrated circuits by adding deuterium to the buried insulator (BOX) in the wafer, so that deuterium in the buried insulator diffuses upward to the semiconductor device layer to passivate defects in the entire processing.

Another feature of the invention is a semiconductor substrate having a deuterated buried insulator.

Yet another feature of the invention is the formation of a semiconductor device having a deuterated buried insulator.

Yet another feature of the invention is formation of semiconductor substrate and device having a deuterated buried insulator so that deuterium in the buried insulator diffuses upward to passivate defects in the gate insulator and at the interface between the gate insulator and semiconductor body.

Yet another feature of the invention is formation of semiconductor substrate and device having a deuterated buried insulator so that deuterium in the buried insulator diffuses upward to the gate insulator interface to replace deuterium that has diffused away from the interface.

Yet another feature of the invention is semiconductor substrate having a deuterated buried insulator so that deuterium in the buried insulator diffuses upward to the gate insulator interface to passivate the interface defects in the entire processing.

### BRIEF DESCRIPTION OF THE DRAWINGS

FIG. 1 shows a step in the wafer bonding process.

FIG. 2 shows a bonded wafer with a deuterated buried oxide.

FIG. 3 shows schematically the process of forming a deuterated SIMOX wafer.

FIG. 4 shows a cross section of a FET on a deuterated wafer.

FIG. 5 shows schematically the process of adding deuterium to a wafer before bonding.

### DETAILED DESCRIPTION

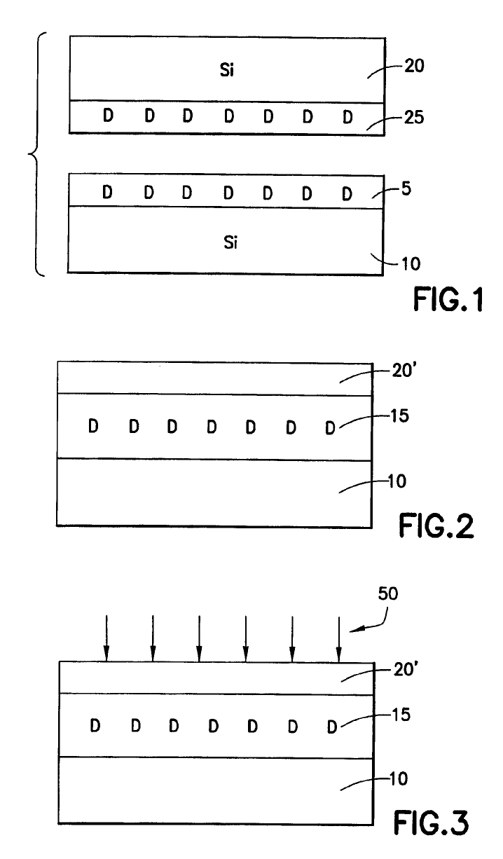

FIG. 1 and FIG. 2 show in simplified form the wafer bonding process according to the invention. Bonded wafers are commercially available and have reached an advanced stage of development. Typically, two wafers each have a layer of oxide formed on one surface, referred to as a bonding surface, the two oxide layers being pressed together at an elevated temperature to bond the wafers and to form the buried oxide (BOX), also referred to as a separation layer or a layer of bonding insulator, that isolates the device layer from the substrate.

FIG. 1 shows wafer substrate 10 has a layer of oxide 5 formed on it, preferably by a wet oxidation process. Deuterium, denoted by the letters D, has been incorporated in the oxide by any of a number of methods (illustrated in FIG. 5). A counterpart wafer 20 has a layer of oxide 25 formed on it.

For example, at least one chemical species containing deuterium may be used to form the oxide. The oxide can be formed by oxidation or deposition process such as chemical vapor deposition (CVD). For example, D2, D2O, and/or ND3 can be used in the oxidation process and SiD4 and/or deuterated tetra-ethyl-ortho-silicate (TEOS) can be used in the deposition process. Alternatively, the oxide (or the substrate before oxidation) may be exposed to a deuterium plasma. As another alternative, deuterium may be implanted in the oxide (or the substrate before oxidation). It is an advantageous feature of the invention that the depth of penetration of the deuterium is not important, since the normal diffusion process will even out the distribution. FIG. 5 illustrates schematically the deuteration process, in which box 30 represents the gas source in the oxidation process or the starting materials in the deposition process, the plasma and its source is the plasma process, or the implanter and the ions in the ion implantation process.

FIG. 2 shows the two layers of oxide bonded together in a conventional process, well known to those skilled in the art, to form the combined wafer having substrate 10, BOX 15, and device layer 20′ that has been formed by thinning the substrate 20 in a conventional process such as cleaving, lapping, chemical-mechanical polishing and/or etching to a thickness appropriate to the then-current technology. At present, device layers are about 50 to 100 nanometers thick.

The quantity of deuterium incorporated in the BOX (referred to as a reserve concentration) is not critical and need only be sufficient to supply deuterium to passivate the defects in the interface between the device layer and the gate insulator and replace the amount that diffuses away from the interface sites in the interface between the device layer and the gate insulator or that is dislodged by hot electrons in the course of transistor operation, so that a stable concentration of deuterium is maintained in the device layer. The term “stable” as used herein does not necessarily mean uniform and a slowly-varying distribution of deuterium having a peak in the BOX and a gradient extending to a lower value at the interface between the device layer and the gate insulator. Since the diffusion rate at normal operating temperature of an integrated circuit is much lower than the rate during processing, the concentration of deuterium at the interface will vary so slowly during operation of the finished device that the device characteristics will not noticeably change.

As indicated above, the location and distribution of the deuterium is not important, since the hot processes in transistor formation will diffuse the initial concentration. Thus, the deuterium may be deposited on the top surface of substrate 10 before oxidation, combined with the oxide during the oxidation process, or implanted in the oxide after the oxidation.

FIG. 3 indicates an alternative method of forming the BOX, referred to as the Separation by Implantation of Oxygen (SIMOX) process, in which oxygen ions are implanted into the wafer to form the BOX. In this process, base 10 is the same as before in FIG. 1, but BOX 15 is formed by the distribution of oxygen ions 50 that have an energy sufficient to penetrate to the depth of device layer 20′ followed by a high temperature anneal. Deuterium species may be added to the ion stream or implanted before or after the oxygen ions. Alternatively, deuterium species may be implanted into the BOX layer after the high temperature anneal.

Whether wafers with a deuterated buried insulator are produced by bonding or by implantation does not matter for the practice of the invention.

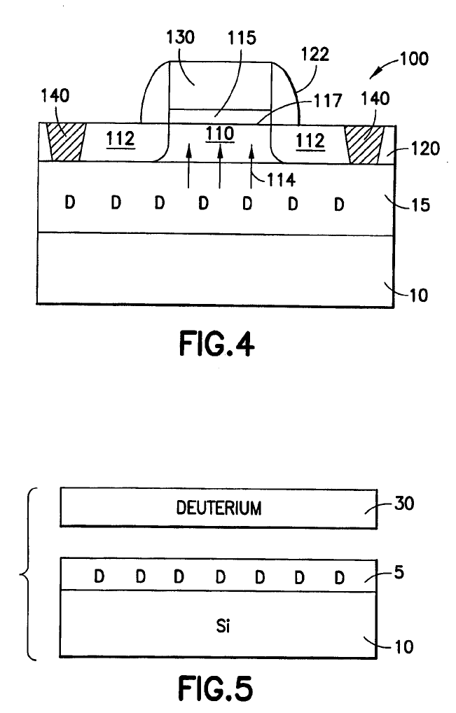

FIG. 4 shows in cross section a completed planar field effect transistor on a substrate according to the invention. The transistor, denoted generally with numeral 100, and representing schematically the set of transistors in an integrated circuit, has silicon body 110 formed in device layer 120, adjacent to deuterated BOX 15 and bracketed by source and drain 112. Gate oxide 115 is disposed above silicon body 110 and below gate electrode 130. Conventional sidewall spacers 122 separate the gate electrode from the source and drain. Shallow trench isolation (STI) 140 isolates the transistor from neighboring devices.

In the course of the transistor formation process, deuterium in BOX 15 will diffuse vertically upward and passivate defects such as dangling bonds at interface 117 between the top surface of device layer 120 and gate oxide 115.

Furthermore, since the concentration of deuterium in BOX 15 (referred to as a reserve concentration) is higher than the concentration at the interface 117, BOX 15 acts as a reserve source of deuterium and supplies additional deuterium to diffuse upward to replace deuterium that diffuses into the gate electrode. Alternatively, deuterium can diffuse through STI 140 to the device layer 120 and other layers above the layer 120. The magnitude of the deuterium concentration will be set empirically to supply enough deuterium to perform the passivation and supply replacement deuterium. Diffusion in the horizontal direction is not a concern because the concentration of deuterium is substantially constant to the left and right of the transistor body, so that lateral diffusion out of the transistor is balanced by diffusion in.

A vertical diffusion path from the BOX to the interface 117 is denoted by the vertical arrows 114 extending across body 110.

Preferably, the deuterium is added to the BOX such that the concentration peaks at or near the top surface of the BOX, so that the diffusion path to the interface is as short as possible, thereby encouraging the deuterium to diffuse upward rather than downward. Those skilled in the art will appreciate that the gate insulator may be oxide, nitride, a mixture of oxide and nitride, and/or other suitable dielectric materials such as hafnium-based high-k dielectric materials; the buried insulator may also contain nitride; the device layer may be a silicon-germanium alloy, germanium or other semiconductor; and the device layer may be strained in a conventional process, well known to those skilled in the art.

While the invention has been described in terms of a single preferred embodiment, those skilled in the art will recognize that the invention can be practiced in various versions within the spirit and scope of the following claims.

1. A method of forming a semiconductor wafer having a device layer of semiconductor separated from a substrate layer by a separation layer of insulator comprising the steps of:
providing first and second semiconductor wafers, each having a bonding surface;
forming a layer of bonding insulator on at least one of said bonding surface;
incorporating deuterium in at least one of said layers of bonding insulator;
bonding said wafers at said bonding insulators, thereby forming a separation layer from said layers of bonding insulator; and
forming a device layer in one of said first and second semiconductor wafers.

2. A method according to claim 1, in which
said step of incorporating deuterium in said separation layer is effected by ion implantation of deuterium.

3. A method according to claim 2, in which said step of implantation of deuterium comprises implanting a reserve concentration of deuterium sufficient to diffuse through said device layer to maintain a stable concentration of deuterium within said device layer by replacing deuterium that diffuses out of said device layer.

4. A method according to claim 2, in which
said semiconductor wafer comprises silicon and said separation layer comprises silicon oxide.

5. (canceled)

6. A method according to claim 1, in which said step of incorporating deuterium is effected by one of oxidation and deposition with at least one starting material containing deuterium before said step of bonding.

7. A method according to claim 1, in which said step of incorporating deuterium is effected by adding deuterium after said step of bonding.

8. A method according to claim 6, in which said step of incorporating deuterium comprises incorporating a reserve concentration of deuterium sufficient to diffuse through said device layer to maintain a stable concentration of deuterium within said device layer by replacing deuterium that diffuses out of said device layer.

9. A method according to claim 1, in which said step of incorporating deuterium is effected by exposing said layer of bonding insulator to a plasma containing deuterium.

10. A method according to claim 9, in which said step of incorporating deuterium comprises incorporating a reserve concentration of deuterium sufficient to diffuse through said device layer to maintain a stable concentration of deuterium within said device layer by replacing deuterium that diffuses out of said device layer.

11. A method according to claim 1, in which said step of incorporating deuterium is effected by implanting deuterium into one of said layers of bonding insulator.

12. A method according to claim 11, in which said step of incorporating deuterium comprises incorporating a reserve concentration of deuterium sufficient to diffuse through said device layer to maintain a stable concentration of deuterium within said device layer by replacing deuterium that diffuses out of said device layer.

13-21. (canceled)

22. A method according to claim 1, in which said step of incorporating deuterium is effected by forming one of said first and second bonding layers by oxidation with at least one starting material containing deuterium.

23. A method according to claim 1, in which said step of incorporating deuterium is effected by forming one of said first and second bonding layers by deposition with at least one starting material containing deuterium.
